(19) United States
(12) Patent Application Publication
(10) Pub. No.: US 2013/0115733 A1
(43) Pub. Date: May 9, 2013

(54) ETCHANT COMPOSITION AND METHOD FOR MANUFACTURING THIN FILM TRANSISTOR USING THE SAME

(71) Applicants: Bong-Kyun KIM, Hwaseong-si (KR); Hong Sick PARK, Suwon-si (KR); Wang Woo LEE, Suwon-si (KR); Young Woo PARK, Seoul (KR); Shin Il CHOI, Hwaseong-si (KR); Sang-Woo KIM, Seongnam-si (KR); Ki-Beom LEE, Seoul (KR); Dae-Woo LEE, Seoul (KR); Sam-Young CHO, Anyang-si (KR); Jeong-Heon CHOI, Cheongju-si (KR)

(72) Inventors: Bong-Kyun KIM, Hwaseong-si (KR); Hong Sick PARK, Suwon-si (KR); Wang Woo LEE, Suwon-si (KR); Young Woo PARK, Seoul (KR); Shin Il CHOI, Hwaseong-si (KR); Sang-Woo KIM, Seongnam-si (KR); Ki-Beom LEE, Seoul (KR); Dae-Woo LEE, Seoul (KR); Sam-Young CHO, Anyang-si (KR); Jeong-Heon CHOI, Cheongju-si (KR)

(73) Assignees: DONGJIN SEMICHEM CO., LTD, Incheon-city (KR); SAMSUNG DISPLAY CO., LTD., Yongin-City (KR)

(21) Appl. No.: 13/547,783

(22) Filed: Jul. 12, 2012

(30) Foreign Application Priority Data
Nov. 8, 2011 (KR) 10-2011-0116085

(51) Int. Cl. H01L 21/465; C09K 13/06; C09K 13/00

(52) U.S. Cl. 438/104; 252/79.1; 252/79.4; 257/E21.46

(57) ABSTRACT

Provided is an etchant composition. The etchant composition according to an exemplary embodiment of the present invention includes ammonium persulfate ((NH₄)₂)S₂O₈, an azole-based compound, a water-soluble amine compound, a sulfonic acid-containing compound, a nitrate-containing compound, and water.

### CROSS-REFERENCE TO RELATED APPLICATION

This application claims priority from and the benefit of Korean Patent Application No. 10-2011-0116085, filed on Nov. 8, 2011, which is incorporated herein by reference for all purposes as if fully set forth herein.

### BACKGROUND OF THE INVENTION

1. Field of the Invention

Exemplary embodiments of the present invention relate to an etchant composition and a method for manufacturing a thin film transistor using the same.

2. Discussion of the Background

A flat panel display has been requested to implement a high resolution, a large area, and a 3D display, which triggers a need for a higher response speed. Particularly, a thin film transistor (TFT) structure with an increased moving speed of electrons at its channel portion is required. Accordingly, a low-resistance material such as copper has been used to form a wire, and a method for using an oxide semiconductor in order to increase the moving speed of electrons in a semiconductor layer has been studied.

A TFT using semiconductor oxides is drawing wide attention because of its excellent characteristics as a chip and its easiness of mass production due to the simple structure and process. In the case of the TFT-liquid crystal display (LCD), it is possible to implement a high speed operation panel by using an oxide TFT having rapid movability as compared to a known a-Si:H TFT.

The oxide semiconductor layer of a TFT is etched during the manufacturing process. Because the etching process can affect the characteristics of the oxide semiconductor layer, improvements in the process can improve the TFT's performance.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide an etchant composition that collectively etches or selectively etches a low resistant wire and a semiconductor layer formed of an oxide semiconductor, and a method for manufacturing a thin film transistor using the same.

Additional features of the invention will be set forth in the description which follows, and in part will be apparent from the description, or may be learned by practice of the invention.

An exemplary embodiment of the present invention provides an etchant composition, including: ammonium persulfate (((NH4)2)S2O8), an azole-based compound, a water-soluble amine compound, a sulfonic acid-containing compound, a nitrate-containing compound, and water.

Another exemplary embodiment of the present invention provides a method for manufacturing a thin film transistor, including: forming a gate electrode on a substrate, forming a gate insulating layer, a semiconductor material layer, a barrier material layer, and a metal wire material layer on the gate electrode, forming a metal wire pattern portion, a barrier pattern portion, and a semiconductor layer to cover the gate electrode and a peripheral area of the gate electrode by patterning a metal wire material layer, a barrier material layer and a semiconductor material layer, and exposing the semiconductor layer disposed on an overlapping portion with the gate electrode by patterning the metal wire pattern portion and the barrier pattern portion, wherein the forming of the metal wire pattern portion, the barrier pattern portion, and the semiconductor layer is performed in one process using a first etchant, the exposing of the semiconductor layer is performed in one process using a second etchant, and the first etchant and the second etchant have different compositions from each other.

According to exemplary embodiments of the present invention, an etchant composition may selectively etch a metal layer and an oxide semiconductor layer constituting a semiconductor layer, or etch such layers in one process.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 to FIG. 4 are scanning electron microscopic pictures that illustrate a metal layer and a semiconductor layer which have been etched by using etchant compositions according to Examples 1 to 4 of the present invention, respectively.

FIG. 5 to FIG. 9 are scanning electron microscopic pictures that illustrate a metal layer and a semiconductor layer which have been etched by using etchant compositions according to Comparative Examples 1 to 5, respectively.

FIG. 10 shows scanning electron microscopic (SEM) pictures that illustrate lateral portions of a metal pattern and a photo pattern manufactured by etching a metal layer according to various durations when the etchant composition according to Example 1 of the present invention is preserved at room temperature.

FIG. 11 shows scanning electron microscopic pictures that illustrate lateral portions of a metal pattern and a photo pattern manufactured by etching a metal layer according to various durations when the etchant composition according to Example 1 of the present invention is contaminated by copper (Cu) ions.

FIG. 12 to FIG. 15 are cross-sectional views that illustrate a method for manufacturing a thin film transistor according to another exemplary embodiment of the present invention.

### DETAILED DESCRIPTION OF THE ILLUSTRATED EMBODIMENTS

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The etchant composition according to an exemplary embodiment of the present invention includes ammonium persulfate ((NH₄)₂)S₂O₈, an azole-based compound, a water-soluble amine compound, a sulfonic acid-containing compound, a nitrate-containing compound, a fluorine-containing compound and residual water.

Ammonium persulfate is a main component that is used to etch a wire layer as an oxidant. A stable compound is formed by etching the wire layer by a reaction represented by the following Formula 1. In the exemplary embodiment, the wire layer may be made of copper.

S₂O₈⁻²+2Cu->2CuSO₄ Formula 1.

In the case where the content of ammonium persulfate is less than about 0.1wt % on the basis of the total weight of the etchant composition, the wire layer may not be easily etched by etchant. In the case where the content of ammonium persulfate is more than about 25 wt %, since the etchant excessively rapidly etches the wire layer, it may be difficult to control an etch time. Accordingly, in the exemplary embodiment, the content of ammonium persulfate is maintained about 0.1 wt % to about 25 wt % on the basis of the total weight of the etchant composition. Particularly, the content of ammonium persulfate may be maintained about 5 wt % to about 20 wt % on the basis of the total weight of the etchant composition.

The azole-based compound includes a nitrogen atom, and is a pentanary hetero ring in which at least one non-carbon atom is included in the ring. The azole-based compound may control the etch rate between the layer materials of upper and/or lower portions of the copper layer by suppressing etching of copper on the wire layer. The azole-based compound may decrease a CD skew of the metal wire.

Examples of the azole-based compound include benzotriazole, aminotetrazole, aminotetrazole potassium salt, imidazole, and pyrazole.

In the case where the content of the azole-based compound is less than about 0.01 wt % on the basis of the total weight of the etchant composition, it may be hard to control the etch rate between the copper layer and lower layer, and the straightness of the metal pattern is significantly decreased. In the case where the content of the azole-based compound is more than about 2 wt %, the etch capability of the etchant is decreased by the azole-based compound. Accordingly, the content of the azole-based compound may be maintained about 0.01 wt % to about 2 wt % on the basis of the total weight of the etchant composition.

In the exemplary embodiment, water-soluble amine means a compound that is soluble in water among compounds with a hydrogen atom of ammonia (NH₃) being replaced with a hydrocarbon residual group, and acts as an acidity control agent in the etchant.

Generally, the water-soluble amine may be any one selected from the group consisting of glycine, an iminodiacetic acid, lysine, threonine, serine, an asparaginic acid, parahydroxyphenyl glycine, dihydroxyethyl glycine, alanine, an anthranilic acid, tryptophan, a sulfamic acid, a cyclohexylsulfamic acid, an aliphatic amine sulfonic acid, taurine, an aliphatic amine sulfinic acid, and an aminoethanesulfinic acid. These may be used alone or in combination of two or more kinds. The sulfamic acid and iminodiacetic acid may be used as an example of water-soluble amine.

In the case where the content of water-soluble amine is less than about 0.1 wt % on the basis of the total weight of the etchant composition, an effect by a copper ion is not decreased, and in the case where the content is more than about 15 wt %, the metal layer is excessively rapidly etched with ammonium persulfate, such that the metal pattern that is a resulting material formed by etching the metal layer may be short-circuited.

Accordingly, the content of water-soluble amine may be maintained about 0.1 wt % to about 15 wt % on the basis of the total weight of the etchant composition. In the case where one compound as water-soluble amine is used alone, the content of water-soluble amine may be about 0.1 wt % to about 15 wt %. Unlike this, in the case where at least two compounds as water-soluble amine are mixed and used, the content of water-soluble amine may be substantially the same as the sum of contents of the compounds, and the sum of contents of the compounds may be about 0.1 wt % to about 15 wt %.

For example, in the exemplary embodiment, water-soluble amine may include about 0.05 wt % to about 10 wt % of a sulfamic acid and about 0.05 wt % to about 5 wt % of an iminodiacetic acid. Accordingly, the range of the sum of contents of the sulfamic acid and iminodiacetic acid may be substantially the same as the range of the content of water-soluble amine.

In the exemplary embodiment, the nitrate-containing compound is a compound that contains nitrate ions (NO₃⁻), and forms an excellent taper etch profile as an etch control agent in the etchant of the present composition. Examples of such nitride-containing compound includes a composition that is selected from the group consisting of ammonium nitrate (NH₄NO₃), calcium nitrate (Ca(NO₃)₂), zinc nitrate (Zn(NO₃)₂), sodium nitrate (NaNO₃), aluminum nitrate (Al(NO₃)₃), barium nitrate (Ba(NO₃)₂), cerium nitrate (Ce(NO₃)₃), copper nitrate (Cu(NO₃)₂), iron nitrate (Fe(NO₃)₃), lithium nitrate (LiNO₃), magnesium nitrate (Mg(NO₃)₂), manganese nitrate (Mn(NO₃)₂), silver nitrate (Ag₃NO₃), and potassium nitrate (KNO₃).

If the content of the nitrate-containing compound is less than 0.1 wt %, the compound is less likely to function as the etch control agent, and in the case where the content is more than 5 wt %, the etch rate may be deteriorated to cause a problem when the compound is applied to a mass-production process.

In the exemplary embodiment, the fluorine-containing compound means a compound that contains fluorine, and is a main component that selectively etches the oxide semiconductor layer beneath copper. Examples of the fluorine-containing compound include a hydrofluoric acid (HF), sodium fluoride (NaF), sodium bifluoride (NaHF₂), ammonium fluoride (NH₄F), ammonium bifluoride (NH₄HF₂), ammonium fluoroborate (NH₄BF₄), potassium fluoride (KF), potassium bifluoride (KHF₂), aluminum fluoride (AlF₃), a fluoroboric acid (HBF₄), lithium fluoride (LiF₄), potassium tetrafluoroborate (KBF₄), and calcium fluoride (CaF₂).

When the fluorine-containing compound is removed in the content of 0 wt %, in the thin film transistor, it is possible to etch a single copper layer and a copper manganese/copper (CuMn/Cu) multilayer constituting a source electrode and a drain electrode, and a gallium zinc oxide layer (GZO layer) acting as a barrier of the semiconductor layer, and the indium gallium zinc oxide layer (IGZO layer) selectively remains. In addition, when the content is in the range of 0.1wt % to 2wt %, it is possible to etch all the single copper layer and the copper manganese/copper (CuMn/Cu) multilayer constituting the source/drain electrodes and the gallium zinc oxide (GZO) and indium gallium zinc oxide (IGZO) layer materials constituting the semiconductor layer.

If the content of the fluorine-containing compound is less than 0.1 wt %, in the semiconductor layer, it may be difficult to etch indium gallium zinc oxide (IGZO), and in the case where the content is more than 2 wt %, defects may be caused by etching the lower insulating layer.

In the exemplary embodiment, unless otherwise specified with respect to the content of water, the content of water corresponds to residual content obtained by subtracting wt % of other components other than water from 100% of the entire etchant. According to the exemplary embodiment, semiconductor grade water or ultrapure water may be used as the water in the etchant.

The ranges of the etchants or etchant compositions as described in the exemplary embodiments should be construed to cover the range of the weight ratios of the etchants or etchant compositions outside the specified range if using etchants or etchant compositions out of such ranges generates substantially the same effect or is apparent to those skilled in the art.

### Experimental Example

With respect to the etchant composition according to the exemplary embodiment, etch characteristics were compared to each other by manufacturing the etchants of Example 1 to Example 4 and Comparative Example 1 to Comparative Example 5 as described in the following Table 1. The compositions of Example 1 to Example 4, and Comparative Example 1 to Comparative Example 5 are described in the following Table 1, and all numerical values are in terms of weight ratios (wt %).

TABLE 1

| | | | Water- | Water- | | | |
|---|---|---|---|---|---|---|---|
| | | Azole- | soluble | soluble | Sulfonic | | |
| | | based | amine | amine | acid | Nitrate | |
| | APS | compound | compound 1 | compound 2 | compound | compound | Fluoride |
| Example 1 | 12 | 0.5 | 10 | 4 | 4 | 4 | 0.9 |
| Example 2 | 15 | 0.3 | 5 | 3 | 4 | 4 | 0.5 |
| Example 3 | 8 | 0.3 | 10 | 5 | 3 | 5 | 0.5 |
| Example 4 | 12 | 0.5 | 10 | 4 | 4 | 4 | — |
| Comparative | 12 | 2.5 | 10 | 4 | 4 | 4 | 0.9 |
| Example 1 | | | | | | | |
| Comparative | 12 | 0.5 | — | — | 4 | 4 | 0.9 |
| Example 2 | | | | | | | |
| Comparative | 12 | 0.5 | 10 | 4 | — | 4 | 0.9 |
| Example 3 | | | | | | | |
| Comparative | 12 | 0.5 | 10 | 4 | 4 | — | 0.9 |
| Example 4 | | | | | | | |
| Comparative | 12 | 0.5 | 15 | 4 | 4 | 4 | 0.9 |
| Example 5 | | | | | | | |

In Table 1, APS represents ammonium persulfate, water-soluble amine compound 1 represents the sulfamic acid, and the water-soluble amine compound 2 represents the iminodiacetic acid.

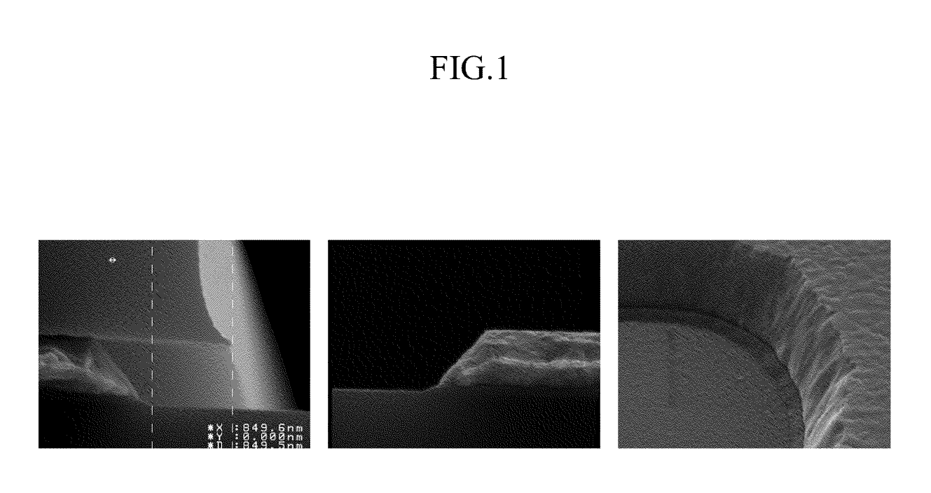

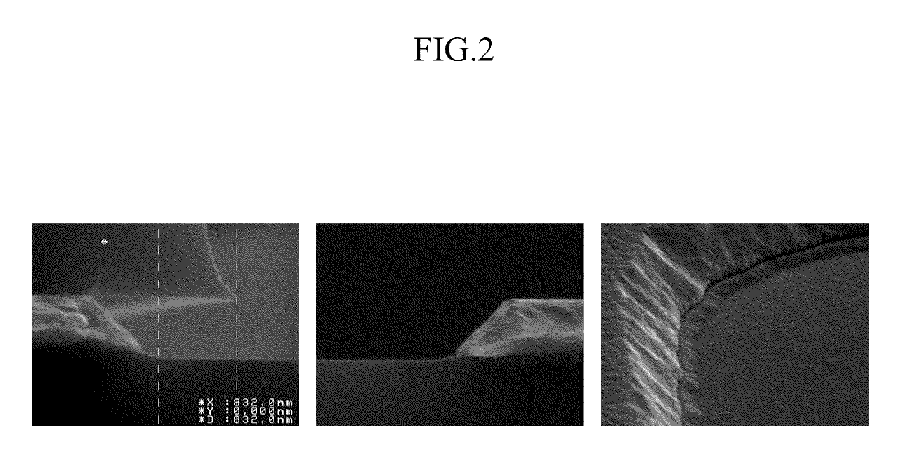

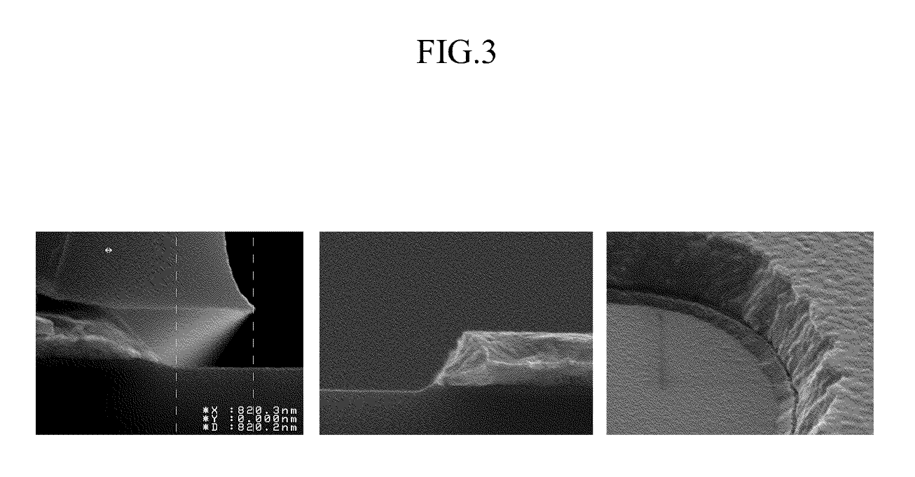

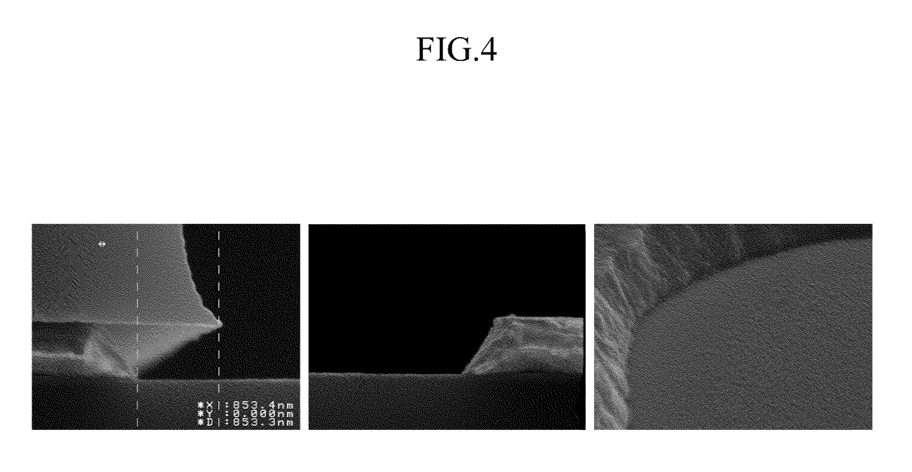

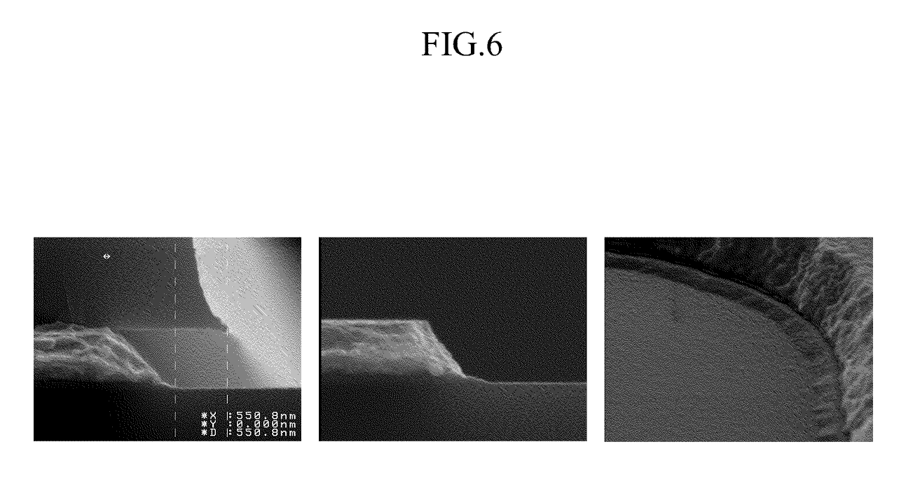

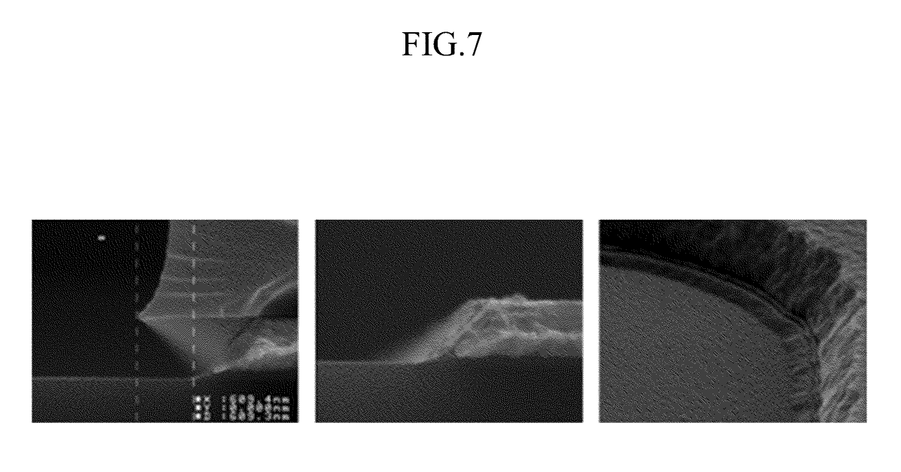

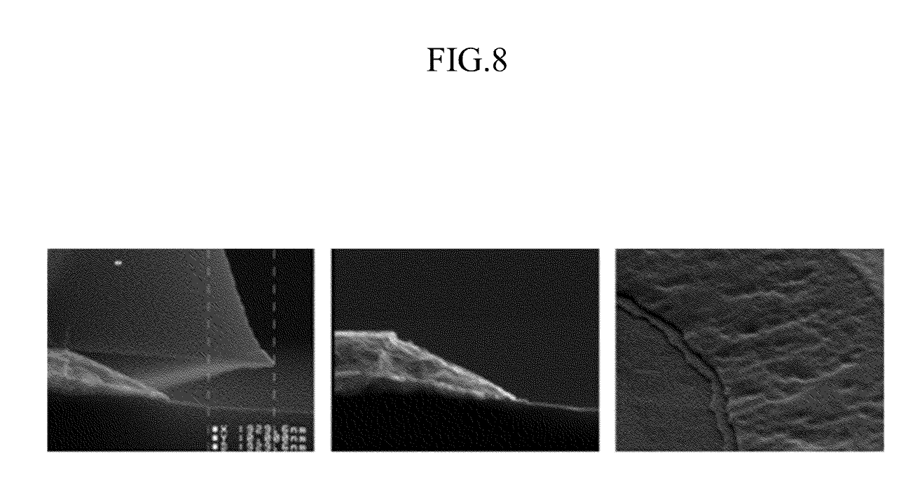

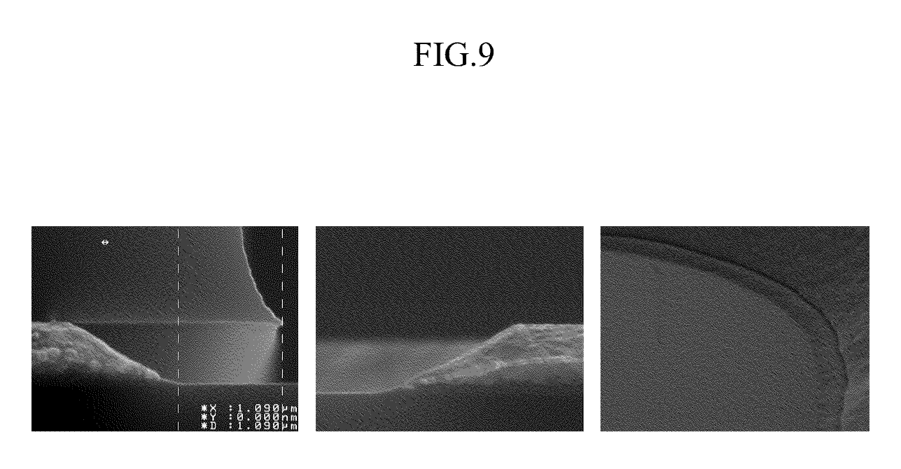

In detail, the etch rate, critical dimension (CD) Skew and taper angle of the etchants of the Examples and Comparative Examples were evaluated through the overetching test in which the indium gallium zinc oxide/gallium zinc oxide/copper/copper manganese (IGZO/GZO/Cu/CuMn) four-layered layer having the structure in which the source/drain electrodes and semiconductor layer were laminated was etched more than 100% based on time. In addition, etched lateral cross-sections of the four-layered layer were observed by the scanning electron microscopic pictures. The results are described in the following Table 2 and FIG. 1 to FIG. 9.

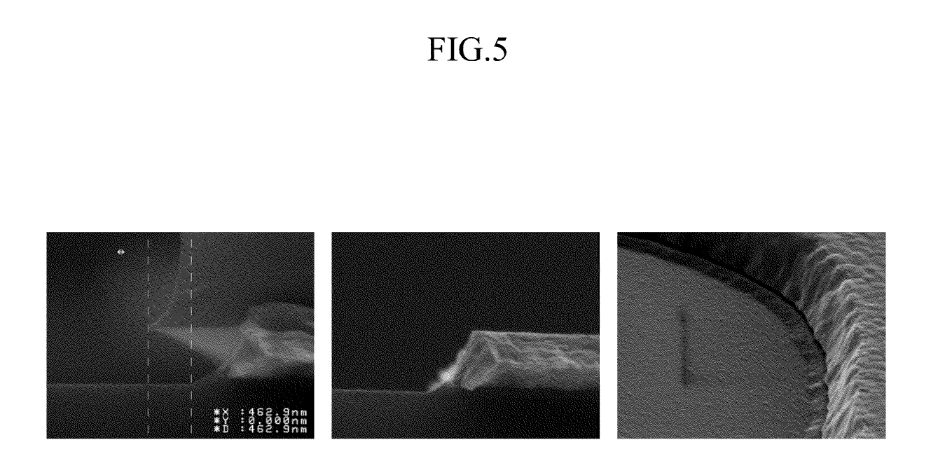

FIG. 1 to FIG. 4 are scanning electron microscopic pictures that illustrate a metal layer and a semiconductor layer which have been etched by using etchant compositions according to Examples 1 to 4 of the present invention, respectively, and FIG. 5 to FIG. 9 are scanning electron microscopic pictures that illustrate a metal layer and a semiconductor layer which have been etched by using etchant compositions according to Comparative Examples 1 to 5, respectively.

TABLE 2

| | Copper | S/D CD | S/D taper | Performance of |
|---|---|---|---|---|
| | etch EPD | Skew | angle | etching of the |
| | (sec) | (um) | (°) | IGZO layer |
| Example 1 | 29 | 0.849 | 50 | ◯ |
| Example 2 | 29 | 0.832 | 50 | ◯ |
| Example 3 | 29 | 0.820 | 60 | ◯ |
| Example 4 | 25 | 0.853 | 55 | X |
| Comparative | 34 | 0.462 | 53 | ◯ |
| Example 1 | | | | |
| Comparative | 34 | 0.550 | 50 | ◯ |
| Example 2 | | | | |
| Comparative | 33 | 0.609 | 50 | ◯ |
| Example 3 | | | | |
| Comparative | 30 | 0.929 | 30 | ◯ |
| Example 4 | | | | |
| Comparative | 26 | 1.090 | 35 | ◯ |
| Example 5 | | | | |

The EPD (End Point Detect) means a state in which the lower layer is exposed to the etchant after the layer material to be etched is completely etched by the etchant. As the EPD value is decreased, the etch capability is increased. The CD Skew represents a distance between an end of a photoresist and an end of the metal layer, and the distance should be within an appropriate range in order to reduce the possibility of occurrence of a step portion and to ensure uniform taper etching.

The source electrode/drain electrode (S/D) wire is disposed on the layer material. The width of the S/D wire is important. If an inclination is low, the inclination length is extended as compared to an area of a lower portion of an inclined surface, which narrows a wire width of the upper portion of the metal. Higher inclination favorably provides a wider wire.

In Table 2, the CD Skew of each S/D line may be maintained in the range of about 0.7 μm to about 0.9 μm. With reference to Table 2, the CD Skew of each S/D line made from the etchant composition according to Examples 1 to 4 of the present invention is in the range of about 0.7 μm to about 0.9 μm. While the etchant compositions according to Comparative Examples 4 and 5 have the rapid EPD, the CD Skew of the S/D line formed by using the same is relatively large, and the wire width becomes narrow by forming the low inclination.

Based on the above description, it can be seen that, in the case where the S/D line is formed by using the etchant compositions according to Examples 1 to 4 of the present invention, as compared to the case where the etchant compositions according to Comparative Examples 1 to 5 are used, a relatively excellent etch rate can be ensured and the taper angle can be controlled so that the angle is in the range of about 50° to about 60°.

This profile range provides the high inclination causing maintenance of the wire width of the S/D. In addition, since the CD skew is excellent, it can be seen that the straightness of the semiconductor layer pattern including the S/D line is excellent and stability is good.

In the case of Example 4 of Table 1, the composition from which the fluorine-containing compound is removed may act as the channel portion in the semiconductor layer by selectively suppressing etching of the lowermost IGZO layer.

In addition, the etchant composition according to Example 1 of the present invention was manufactured, and storage stability and etch performance with respect to the number to be treated were verified. The storage stability was evaluated by performing the verification at a low temperature of 10° C. for 9 days, and the accumulative inclination was evaluated by inflicting contamination using the copper (Cu) ion in an amount of 500 ppm an hour for 12 hours. The following Table 3 represents the evaluation result of the storage stability, and the following Table 4 represents the etch result with respect to the accumulative inclination.

TABLE 3

| Etch | | | | | | | | |
|---|---|---|---|---|---|---|---|---|
| characteristic | 0 day | | 3 days | | 6 days | | 9 days | |
| EPD | 29 | sec | 29 | sec | 29 | sec | 29 | sec |
| 100% O/E CD | 0.820 | um | 0.773 | um | 0.837 | um | 0.797 | um |
| Skew | | | | | | | | |

| | | | | |
|---|---|---|---|---|
| Taper Angle | 50° | 52° | 48° | 50° |

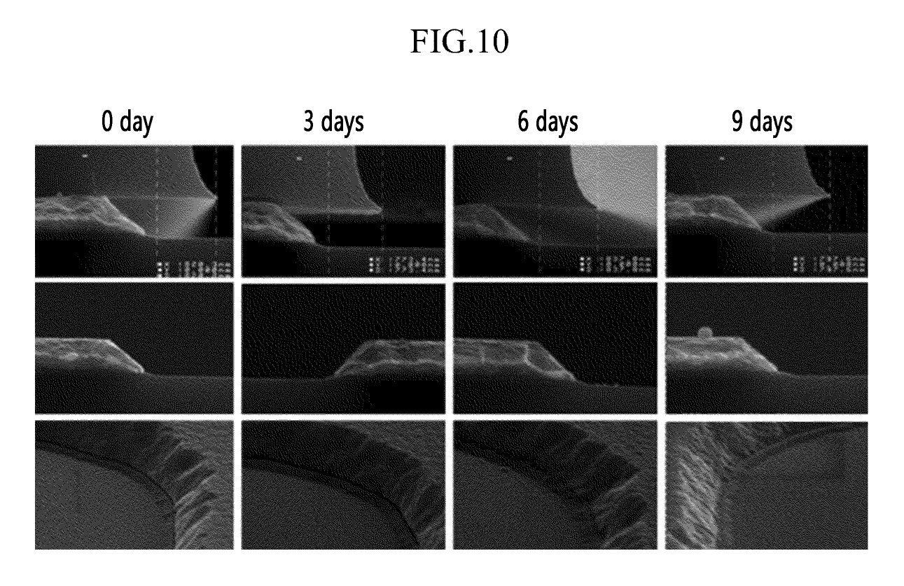

FIG. 10 shows scanning electron microscopic (SEM) pictures that illustrate lateral portions of a metal pattern and a photo pattern manufactured by etching a metal layer according to various durations when the etchant composition according to Example 1 of the present invention is preserved at room temperature.

With reference to Table 3 and FIG. 10, the etch characteristic of the etchant composition according to Example 1 of the present invention is not changed to a substantial degree until at least about 9 days. Therefore, there is an advantage that until about 9 days of the storage at the low temperature, the initial performance may be maintained without a change in the etch characteristic.

TABLE 4

| Etch | 0 ppm/ | | 2,000 ppm/ | | 4,000 ppm/ | | 6,000 ppm/ | |
|---|---|---|---|---|---|---|---|---|
| characteristic | 0 hr | | 4 hr | | 8 hr | | 12 hr | |
| EPD | 29 | sec | 29 | sec | 29 | sec | 29 | sec |
| 100% O/E CD | 0.826 | um | 0.826 | um | 0.843 | um | 0.802 | um |
| Skew | | | | | | | | |

| | | | | |
|---|---|---|---|---|
| Taper Angle | 50° | 50° | 51° | 52° |

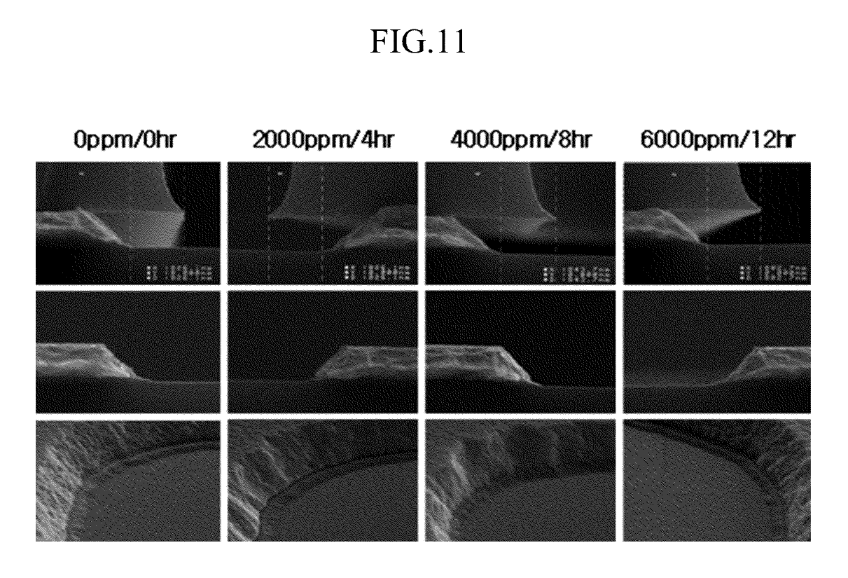

Table 4 and FIG. 11 show scanning electron microscopic pictures that illustrate lateral portions of a metal pattern and a photo pattern manufactured by etching a metal layer according to various durations when the etchant composition according to Example 1 of the present invention is contaminated by copper (Cu) ions.

With reference to Table 4 and FIG. 11, it can be seen that the etch characteristic of the etchant composition according to Example 1 of the present invention is not changed to a substantial degree until the concentration of the copper ions reaches about 6,000 ppm. That is, Example 1 of the present invention is advantageous in that even though the indium gallium zinc oxide/gallium zinc oxide/copper/copper manganese (IGZO/GZO/Cu/CuMn) multilayer including the semiconductor layer and S/D wire is etched several times, the initial etch performance may be maintained.

Hereinafter, a method for manufacturing a thin film transistor using the etchant composition as described above will be described.

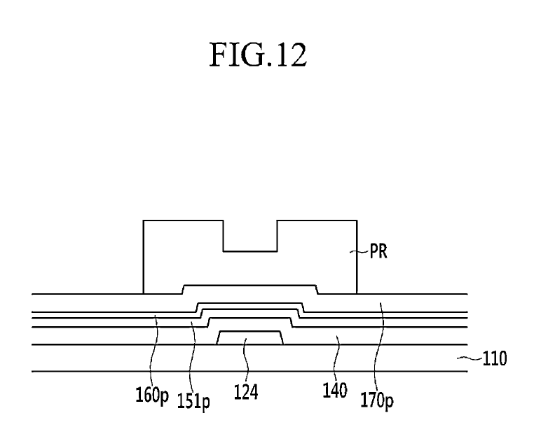

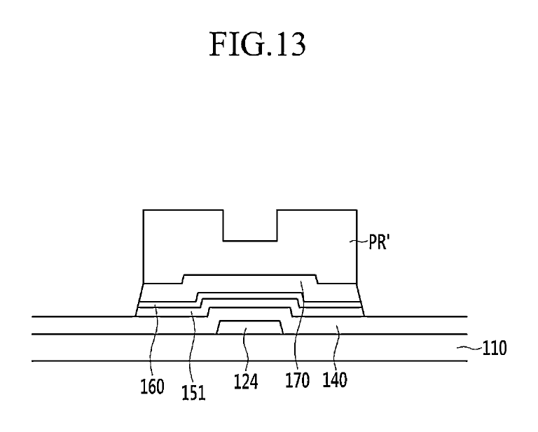

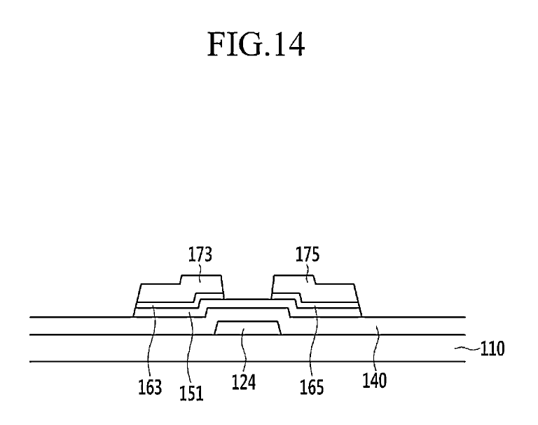

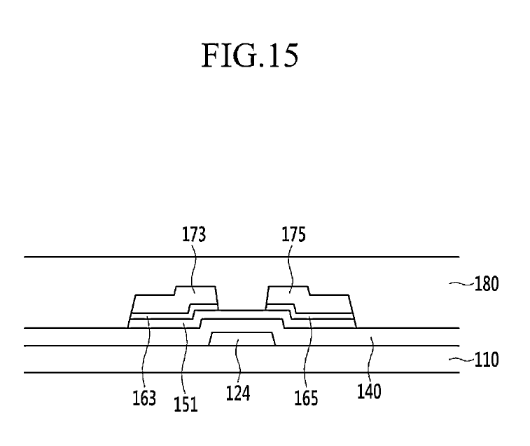

FIG. 12, FIG. 13, FIG. 14, and FIG. 15 are cross-sectional views that illustrate a method for manufacturing a thin film transistor according to another exemplary embodiment of the present invention.

With reference to FIG. 12, a gate electrode 124 is formed on an insulation substrate 110, and a gate insulating layer 140 is formed so as to cover the gate electrode 124.

A semiconductor material layer 151p, a barrier material layer 160p, and a metal wire material layer 170p are formed on the gate insulating layer 140. Here, the semiconductor material layer 151p is made from oxide including at least one of indium, gallium, zinc and tin, or hafnium indium zinc oxide (HfIZO). In addition, the barrier material layer 160p may be formed of gallium zinc oxide (GZO) or indium zinc oxide (IZO).

The metal wire material layer 170p may be formed of copper, but is not limited thereto, and may be formed of a dual layer that is formed of a lower layer including copper and an upper layer including a copper manganese alloy.

A photoresist pattern (PR) is formed on the metal wire material layer 170p. The photoresist pattern (PR) overlaps the gate electrode 124 and covers the peripheral area of the gate electrode 124. In this case, a thickness of a portion overlapping the gate electrode 124 is smaller than a thickness of a portion covering the peripheral area of the gate electrode 124. A portion on which the photoresist pattern (PR) is thinly formed corresponds to a position on which a channel portion of the thin film transistor is formed.

With reference to FIG. 13, the metal wire material layer 170p, the barrier material layer 160p, and the semiconductor material layer 151p are sequentially etched by using the first etchant. In this case, the gate insulating layer 140 is exposed by etching the metal wire material layer 170p, the barrier material layer 160p, and the semiconductor material layer 151p disposed at a portion around the gate electrode 124, and the metal wire material layer 170p is exposed by removing the photoresist pattern (PR) disposed at the portion overlapping the gate electrode 124. The gate electrode 124 and a metal wire pattern portion 170, a barrier pattern portion 160 and a semiconductor layer 151, that cover the peripheral portion of the gate electrode, are formed accordingly.

The first etchant includes ammonium persulfate ((NH₄)₂)S₂O₈, an azole-based compound, a water-soluble amine compound, a sulfonic acid-containing compound, a nitrate-containing compound, a fluorine-containing compound and residual water. The content with respect to the etchant composition according to an Example of the present invention may be applied to the first etchant.

If the etching is completed by the first etchant, a photoresist pattern (PR′) that is lower than the photoresist pattern (PR) of FIG. 12 is formed.

With reference to FIG. 14, a metal wire pattern portion 170 and a barrier pattern portion 160 that are exposed between the photoresist patterns (PR′) of FIG. 13 are sequentially etched by using the second etchant. When the metal wire pattern portion 170 and the barrier pattern portion 160 are sequentially etched, a source electrode 173 and a drain electrode 175 facing each other with respect to the gate electrode 124 are formed, barrier layers 163 and 165 are formed between the source electrode 173 and the semiconductor layer 151, and between the drain electrode 175 and the semiconductor layer 151, respectively.

The barrier layers 163 and 165 may reduce the possibility of the component such as copper included in the source/drain electrodes 173 and 175 to be diffused into the channel portion of the thin film transistor.

The second etchant includes ammonium persulfate ((NH₄)₂)S₂O₈, an azole-based compound, a water-soluble amine compound, a sulfonic acid-containing compound, a nitrate-containing compound, and residual water. The content with respect to the etchant composition according to an Example of the present invention may be applied to the second etchant.

Since the fluorine-containing compound is omitted in the second etchant as compared to the first etchant, the metal wire pattern portion 170 that is formed of the single copper layer or copper/copper manganese multilayer and the barrier pattern portion 160 that is formed of gallium zinc oxide (GZO) may be etched, and the semiconductor layer 151 that is formed of indium gallium zinc oxide (IGZO) selectively remains.

As set forth above, since the second etchant may etch the metal wire pattern portion 170 and the barrier pattern portion 160 together, it is unnecessary to perform a dry etch process for etching a barrier layer. Accordingly, a process time and a cost may be decreased, and since the first etchant and the second etchant according to the Examples do not use hydrogen peroxide, a heating phenomenon, a deterioration of stability of the etchant, and addition of an expensive stabilizing agent may be reduced.

Referring to FIG. 15, a passivation layer 180 is formed by covering the gate insulating layer 140, the source electrode 173, the drain electrode 175 and the exposed semiconductor layer 151. The passivation layer 180 may be formed of silicon oxide or nitrogen oxide. While the exemplary embodiment illustrates a bottom gate TFT, the principle of the present invention is not limited thereto, and also applicable to a top gate TFT.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An etchant composition, comprising:
ammonium persulfate ((NH₄)₂)S₂O₈;
an azole-based compound;
a water-soluble amine compound;
a sulfonic acid-containing compound;
a nitrate-containing compound; and
water.

2. The etchant composition of claim 1, further comprising:
a fluorine-containing compound.

3. The etchant composition of claim 2, wherein:
a content of the fluorine-containing compound is about 0.1 wt % to about 2 wt % of the etchant composition.

4. The etchant composition of claim 3, wherein:
a content of the ammonium persulfate is about 0.1 wt % to about 25 wt % of the etchant composition.

5. The etchant composition of claim 4, wherein:
a content of the azole-based compound is about 0.01 wt % to about 2 wt % of the etchant composition.

6. The etchant composition of claim 5, wherein:
a content of the water-soluble amine compound is about 0.1 wt % to about 15 wt % of the etchant composition.

7. The etchant composition of claim 6, wherein:
a content of the sulfonic acid-containing compound is about 0.1 wt % to about 5 wt % of the etchant composition.

8. The etchant composition of claim 7, wherein:
a content of the nitrate-containing compound is about 0.1 wt % to about 5 wt % of the etchant composition.

9. The etchant composition of claim 1, wherein:
the water-soluble amine compound comprises at least one of a sulfamic acid and an iminodiacetic acid.

10. The etchant composition of claim 1, wherein:
a content of the ammonium persulfate is about 0.1 wt % to about 25 wt % of the etchant composition, a content of the azole-based compound is about 0.01 wt % to about 2 wt % of the etchant composition, a content of the water-soluble amine compound is about 0.1 wt % to about 15 wt % of the etchant composition, a content of the sulfonic acid-containing compound is about 0.1 wt % to about 5 wt % of the etchant composition, and a content of the nitrate-containing compound is about 0.1 wt % to about 5 wt % of the etchant composition.

11. A method for manufacturing a thin film transistor, comprising:
forming a gate electrode on a substrate;
forming a gate insulating layer, a semiconductor material layer, a barrier material layer and a metal wire material layer on the gate electrode;
forming a metal wire pattern portion, a barrier pattern portion, and a semiconductor layer to cover the gate electrode and a peripheral area of the gate electrode by patterning the metal wire material layer, the barrier material layer and the semiconductor material layer; and
exposing the semiconductor layer disposed on an overlapping portion with the gate electrode by patterning the metal wire pattern portion and the barrier pattern portion,
wherein the forming of the metal wire pattern portion, the barrier pattern portion, and the semiconductor layer is performed in one process using a first etchant, the exposing of the semiconductor layer is performed in one process using a second etchant, and
the first etchant and the second etchant have different compositions from each other.

12. The method for manufacturing a thin film transistor of claim 11, wherein:
the semiconductor layer is formed of an oxide semiconductor.

13. The method for manufacturing a thin film transistor of claim 12, wherein:
the metal wire material layer comprises a first metal layer and a second metal layer disposed on the first metal layer,
the first metal layer comprises copper, and the second metal layer comprises a copper manganese alloy.

14. The method for manufacturing a thin film transistor of claim 11, wherein:
the semiconductor layer comprises indiumgalliumzinc oxide (IGZO).

15. The method for manufacturing a thin film transistor of claim 14, wherein:
the barrier material layer comprises gallium zinc oxide (GZO).

16. The method for manufacturing a thin film transistor of claim 11, wherein:
the first etchant comprises ammonium persulfate ((NH₄)₂)S₂O₈, an azole-based compound, a water-soluble amine compound, a sulfonic acid-containing compound, a nitrate-containing compound, a fluorine-containing compound and water.

17. The method for manufacturing a thin film transistor of claim 16, wherein:
the second etchant comprises ammonium persulfate ((NH₄)₂)S₂O₈, the azole-based compound, the water-soluble amine compound, the sulfonic acid-containing compound, the nitrate-containing compound, and water.

18. The method for manufacturing a thin film transistor of claim 17, wherein:
the water-soluble amine compound in the first etchant and the second etchant comprises a sulfamic acid, an iminodiacetic acid, or both the sulfamic acid and the iminodiacetic acid.

19. The method for manufacturing a thin film transistor of claim 18, wherein:
a content of the ammonium persulfate is 0.1 wt % to 25 wt % of the first etchant, a content of the azole-based compound is 0.01 wt % to 2 wt % of the first etchant, a content of the water-soluble amine compound is 0.1 wt % to 15 wt % of the first etchant, a content of the sulfonic acid-containing compound is 0.1 wt % to 5 wt % of the first etchant, and a content of the nitrate-containing compound is 0.1 wt % to 5 wt % of the first etchant.

20. The method for manufacturing a thin film transistor of claim 11, wherein:
the exposing of the semiconductor layer disposed on an overlapping portion with the gate electrode comprises forming a source electrode and a drain electrode facing each other with respect to the gate electrode.
